(19) United States
(12) Patent Application Publication
(10) Pub. No.: US 2023/0329029 A1
(43) Pub. Date: Oct. 12, 2023

(54) Full-color silicon-based organic light-emitting diode (OLED) display device and method

(71) Applicant: ANHUI SEMICONDUCTOR INTEGRATED DISPLAY TECHNOLOGY CO. LTD, Wuhu (CN)

(72) Inventors: Zhengtao ZHAO, Wuhu (CN); Shengfang LIU, Wuhu (CN); Weiwei LI, Wuhu (CN); Xiaojia LIU, Wuhu (CN); Lei LV, Wuhu (CN); Song XU, Wuhu (CN)

(73) Assignee: ANHUI SEMICONDUCTOR INTEGRATED DISPLAY TECHNOLOGY CO. LTD, Wuhu (CN)

(21) Appl. No.: 18/013,944

(22) PCT Filed: Dec. 8, 2021
(86) PCT No.: PCT/CN2021/136459

§ 371 Date: Dec. 30, 2022

(30) Foreign Application Priority Data
Oct. 20, 2020 (CN) 202011122344.1

(51) Int. Cl. H10K 50/818; H10K 50/813; H10K 50/852

(52) U.S. Cl. CPC H10K 50/818; H10K 50/813; H10K 50/852; H10K 2102/351

(57) ABSTRACT

A full-color silicon-based organic light-emitting diode (OLED) display device includes a base plate, a metal anode, an organic functional layer, a metal cathode, a thin film encapsulation (TFE) layer, and a color filter layer that are sequentially stacked from bottom to top. The metal anode includes a first indium tin oxide (ITO) anode layer and a second ITO anode layer each of which has a different thickness. The color filter layer includes a red (R) filter and a blue (B) filter, which are coated on a light-emitting region, which corresponds to the first ITO anode layer, of the TFE layer. The present disclosure overcomes the problem that the top-emission white OLED (WOLED) with a single optical thickness in the prior art is prone to color shift because the R, green (G), and B lights correspond to optical microcavities with different thicknesses.

### CROSS REFERENCE TO THE RELATED APPLICATIONS

This application is the national phase entry of International Application No. PCT/CN2021/136459, filed on Dec. 08, 2021, which is based upon and claims priority to Chinese Pat. Application No. 202011122344.1, filed on Oct. 20, 2020, the entire contents of which are incorporated herein by reference.

### TECHNICAL FIELD

The present disclosure relates to the technical field of full-color silicon-based organic light-emitting diodes (OLEDs), and in particular to a full-color silicon-based OLED display device and method.

### BACKGROUND

Compared with traditional active matrix/organic light-emitting diode (AMOLED) displays, silicon-based OLED microdisplay is based on a single-crystal silicon chip and has a smaller pixel size and a higher integration level with the mature complementary metal-oxide-semiconductor transistor (CMOS) process. The silicon-based OLED microdisplay can be used to prepare near-eye displays that are comparable to large-screen displays, and thus, the silicon-based OLED microdisplay has received widespread attention. Due to its technical advantages and broad market prospect, the silicon-based OLED microdisplay may set off a new wave of near-eye displays in the military and consumer electronics fields, bringing users an unprecedented visual experience.

Limited by the preparation technology of the metal mask, the existing high pixels per inch (PPI) full-color silicon-based OLED products usually use the white OLED (WOLED) plus color filter (CF) technology. To achieve color display, the spectrum of WOLED usually includes a red (R) light peak, a green (G) light peak, and a blue (B) light peak. Since the R light, the G light, and the B light correspond to optical microcavities with different thicknesses, the current structure of top-emission WOLED with a single optical thickness is prone to color shift.

Therefore, in order to overcome the above technical problems, it is necessary to provide a full-color silicon-based OLED display device and method, which can narrow the spectrum, improve the color gamut, improve the efficiency of white-light devices, and meet the requirements of high-brightness products.

### SUMMARY

An objective of the present disclosure is to provide a full-color silicon-based organic light-emitting diode (OLED) display device and method. The present disclosure overcomes the problem that the top-emission white OLED (WOLED) with a single optical thickness in the prior art is prone to color shift because the red (R), green (G), and blue (B) light correspond to optical microcavities with different thicknesses. The present disclosure can narrow the spectrum, improve the color gamut, improve the efficiency of WOLED, and meet the requirements of high-brightness products.

To achieve the above objective, the present disclosure provides a full-color silicon-based OLED display device, including a base plate, a metal anode, an organic functional layer, a metal cathode, a thin film encapsulation (TFE) layer, and a color filter layer that are sequentially stacked from bottom to top.

The metal anode includes a first indium tin oxide (ITO) anode layer and a second ITO anode layer each of which has a different thickness. The color filter layer includes an R filter and a B filter, which are coated on a light-emitting region, which corresponds to the first ITO anode layer, of the TFE layer.

Preferably, the organic functional layer includes a hole injection layer, a hole transport layer, a light-emitting layer, an electron transport layer, and an electron injection layer that are sequentially arranged from bottom to top.

The light-emitting layer includes an R light-emitting unit, a B light-emitting unit, and a G light-emitting unit.

Preferably, the base plate is a single-crystal silicon chip.

The present disclosure further provides a full-color silicon-based OLED display device, including:
selecting a first ITO anode layer and a second ITO anode layer that have different thicknesses; and
coating a color filter layer on a light-emitting region, which corresponds to the first ITO anode layer, of a TFE layer to form two primary colors, namely R and B.

Preferably, the method further includes:
respectively calculating a thickness d_{RB} of an organic layer, which corresponds to an R light-emitting unit and a B light-emitting unit, of an OLED display device and a thickness d_{G} of an organic layer, which corresponds to a G light-emitting unit, of the OLED display device by an equation; and
deriving a relationship between the thickness of the first ITO anode layer and the thickness of the second ITO anode layer from the calculated thicknesses of the two organic layers of the OLED display device, where
the equation for calculating the thickness of the organic layer of the OLED display device is:
$$\sum n {d}_{\text{i}} + \frac{ϕ}{4 π} {λ}_{\text{i}} = m \times \frac{{λ}_{1}}{2} ;$$
where n denotes a refractive index of an organic functional layer in the OLED display device; dᵢ denotes the thickness of the organic functional layer; λᵢ denotes a resonance-enhanced wavelength of a microcavity in the OLED display device; i denotes a type of a light-emitting unit; ϕ denotes a phase shift of light reflected on surfaces of a metal anode and a metal cathode in the OLED display device; and m denotes an order of an emission mode, also known as a microcavity order, which is a positive integer.

Preferably, in the equation for calculating the thickness of the organic layer of the OLED display device:
n is 1.75;
λ_{R} is 618 nm, λ_{G} is 530 nm, and λ_{B} is 460 nm;
d_{RB} is 530 nm; and
d_{G} is 454 nm or 605 nm.

Preferably, the color filter layer includes an R filter and a B filter.

Preferably, the color filter layer is coated on the light-emitting region, which corresponds to the first ITO anode layer, of the TFE layer by a photolithography process.

Preferably, after coating the color filter layer on the light-emitting region, which corresponds to the first ITO anode layer, of the TFE layer, the method further includes:

designing a display driver integrated circuit (IC) to enable the OLED display device to realize full-color display.

According to the above technical solutions, the full-color silicon-based OLED display device and method provided by the present disclosure have the following beneficial effects. The OLED display device uses the first ITO anode layer and the second ITO anode layer with different thicknesses, such that the B light-emitting unit and the R light-emitting unit share a microcavity and the G light-emitting unit uses a separate microcavity. The color filter layer coated on the light-emitting region, which corresponds to the first ITO anode layer, of the TFE layer forms two primary colors, namely R and B, and the G spectrum does not use the color filter process, thereby achieving full-color display. The present disclosure can narrow the spectrum, improve the color gamut, and improve the efficiency of the organic functional layer through the microcavity effect to meet the needs of high-brightness products.

Other features and advantages of the present disclosure will be described in detail in the detailed description section, and those not mentioned herein are prior art or may be implemented by the prior art.

### BRIEF DESCRIPTION OF THE DRAWINGS

The drawings are provided for further understanding of the present disclosure and constitute part of the specification. The drawings and the detailed description of the present disclosure are intended to explain the present disclosure, rather than to limit the present disclosure. In the drawings:

FIG. 1 is a structural diagram of a full-color silicon-based organic light-emitting diode (OLED) display device according to a preferred implementation of the present disclosure;

FIG. 2 shows a spectrum of a light-emitting region corresponding to a first indium tin oxide (ITO) anode layer according to a preferred implementation of the present disclosure;

FIG. 3 shows a spectrum of a light-emitting region corresponding to a second ITO anode layer according to a preferred implementation of the present disclosure;

FIG. 4 is a flowchart of a full-color silicon-based OLED display method according to a preferred implementation of the present disclosure; and

FIG. 5 is a flowchart of the full-color silicon-based OLED display method according to a preferred implementation of the present disclosure.

### REFERENCE NUMERALS

1. base plate; 2. Metal anode; 3. organic functional layer; 4. Metal cathode; 5. thin film encapsulation (TFE) layer; 6. Color filter layer; 201. first ITO anode layer; 202. Second ITO anode layer; 301. hole injection layer; 302. Hole transport layer; 303. light-emitting layer; 304. Electron transport layer; 305. electron injection layer; 601. Red (R) filter; 602. blue (B) filter; 3031. R light-emitting unit; 3032. B light-emitting unit; and 3033. green (G) light-emitting unit.

### DETAILED DESCRIPTION OF THE EMBODIMENTS

The specific implementations of the present disclosure are described in detail below with reference to the drawings. It should be understood that the specific implementations described herein are merely intended to illustrate and interpret the present disclosure, rather than to limit the present disclosure.

In the present disclosure, unless otherwise stated, the orientation terms such as “upper” and “lower” only denote the orientation under normal usage or are understood by those skilled in the art and should not be viewed as a limitation of the term. In the present disclosure, R denotes a red spectrum, G denotes a green spectrum, and B denotes a blue spectrum.

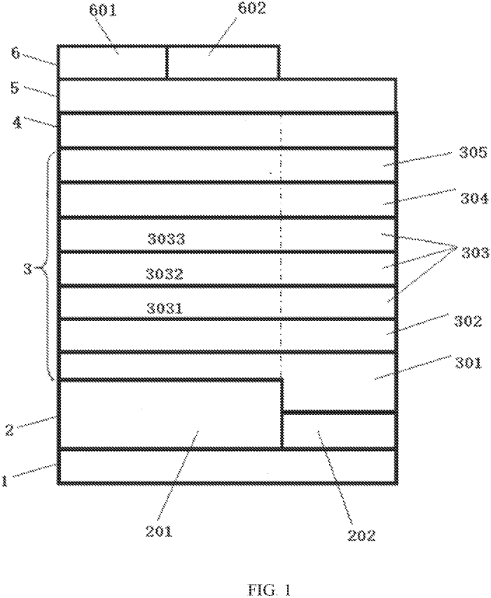

As shown in FIG. 1, the present disclosure provides a full-color silicon-based organic light-emitting diode (OLED) display device. The full-color silicon-based OLED display device includes base plate 1, metal anode 2, organic functional layer 3, metal cathode 4, thin film encapsulation (TFE) layer 5, and color filter layer 6 which are sequentially stacked from bottom to top. The metal anode 2 includes first indium tin oxide (ITO) anode layer 201 and second ITO anode layer 202 which have different thicknesses. The color filter layer includes r®(R) filter 601 and blue (B) filter 602, which are coated on a light-emitting region, which corresponds to the first ITO anode layer 201, of the TFE layer.

According to the above technical solution, the OLED display device uses the first ITO anode layer and the second ITO anode layer with different thicknesses, such that the B light-emitting unit and the R light-emitting unit share a microcavity and the G light-emitting unit uses a separate microcavity. The color filter layer coated on the light-emitting region, which corresponds to the first ITO anode layer, of the TFE layer forms two primary colors, namely R and B, and the G spectrum does not use the color filter process, thereby achieving full-color display. The present disclosure can narrow the spectrum, improve the color gamut, and improve the efficiency of the organic functional layer through the microcavity effect to meet the needs of high-brightness products.

In a preferred implementation, the organic functional layer further includes hole injection layer 301, hole transport layer 302, light-emitting layer 303, electron transport layer 304, and electron injection layer 305 which are sequentially arranged from bottom to top. The light-emitting layer includes R light-emitting unit 3031, B light-emitting unit 3032, and G light-emitting unit 3033, which form an RGB tandem structure.

In a preferred implementation of the present disclosure, the base plate is a single-crystal silicon chip.

According to the above technical solution, the first ITO anode layer and the second ITO anode layer have different thicknesses, such that the B light-emitting unit and the R light-emitting unit share a microcavity and the G light-emitting unit uses a separate microcavity. Two primary colors, namely, B and R, are formed through the color filter layer. The full-color display structure can overcome the problem that the top-emission white tandem structure in the current OLED structure is prone to color shift.

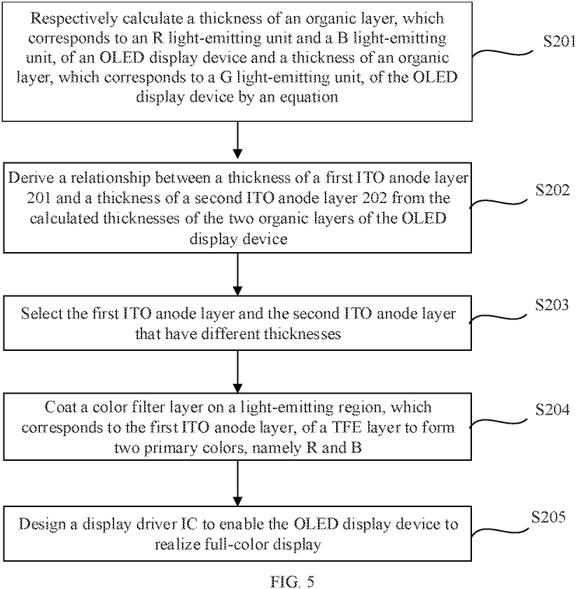

As shown in FIGS. 4 and 5, the present disclosure further provides a full-color silicon-based OLED display method, including:

S101. First ITO anode layer 201 and second ITO anode layer 202 which have different thicknesses are selected.

S102. A color filter layer is coated on a light-emitting region, which corresponds to the first ITO anode layer 201, of a TFE layer to form two primary colors, namely R and B.

According to the above technical solution, the first ITO anode layer 201 and the second ITO anode layer 202 have different thicknesses, such that the B light-emitting unit and the R light-emitting unit share a microcavity and the G light-emitting unit uses a separate microcavity. Two primary colors, namely, B and R, are formed through the color filter layer. The light-emitting region corresponding to the second ITO anode layer 202 directly forms the primary color G. In this way, the full-color display is realized. The full-color display method can overcome the problem that the top-emission white tandem structure in the current OLED structure is prone to color shift.

In a preferred implementation of the present disclosure, the method further includes:

S201. A thickness d_{RB} of an organic layer, which corresponds to an R light-emitting unit and a B light-emitting unit, of an OLED display device and a thickness d_{G} of an organic layer, which corresponds to a G light-emitting unit, of the OLED display device are calculated by an equation.

S202. A relationship between the thickness of the first ITO anode layer 201 and the thickness of the second ITO anode layer 202 is derived from the calculated thicknesses of the two organic layers of the OLED display device.

S203. A first ITO anode layer 201 and a second ITO anode layer 202 that have different thicknesses are selected.

S204. A color filter layer is coated on a light-emitting region, which corresponds to the first ITO anode layer 201, of a TFE layer 5 to form two primary colors, namely R and B.

S205. A display driver integrated circuit (IC) is designed to enable the OLED display device to realize full-color display.

In the method,
the equation for calculating the thickness of the organic layer of the OLED display device is:
$$\sum n {d}_{\text{i}} + \frac{ϕ}{4 π} {λ}_{\text{i}} = m \times \frac{{λ}_{\text{i}}}{2} ;$$
where n denotes a refractive index of an organic functional layer in the OLED display device; dᵢ denotes the thickness of the organic functional layer; λᵢ denotes a resonance-enhanced wavelength of a microcavity in the OLED display device; i denotes a type of a light-emitting unit; ϕ denotes a phase shift of light reflected on surfaces of a metal anode and a metal cathode in the OLED display device; and m denotes an order of an emission mode, also known as a microcavity order, which is a positive integer.

According to the above technical solution, the thickness d_{RB} of the organic layer, which corresponds to the R light-emitting unit and the B light-emitting unit, of the OLED display device and the thickness d_{G} of the organic layer, which corresponds to the G light-emitting unit, of the OLED display device are each calculated. Based on the calculated thicknesses, the relationship between the thickness of the first ITO anode layer and the thickness of the second ITO anode layer is derived. According to these thicknesses, the first ITO anode layer and the second ITO anode layer are selected. With this structure, the B light-emitting unit and the R light-emitting unit share a microcavity and the G light-emitting unit uses a separate microcavity. The spectrum produced by the microcavity shared by the B light-emitting unit and the R light-emitting unit includes R light and B light. Two primary colors, namely, B and R, are formed through the color filter layer. The separate microcavity used by the G light-emitting unit directly forms the primary color G. Finally, the display driver IC is designed, such that the OLED display device realizes a full-color display. The method can simplify the fabrication process of the OLED display device, narrow the spectrum, improve the color gamut, and improve the efficiency of the WOLED through the microcavity effect to meet the needs of high-brightness products.

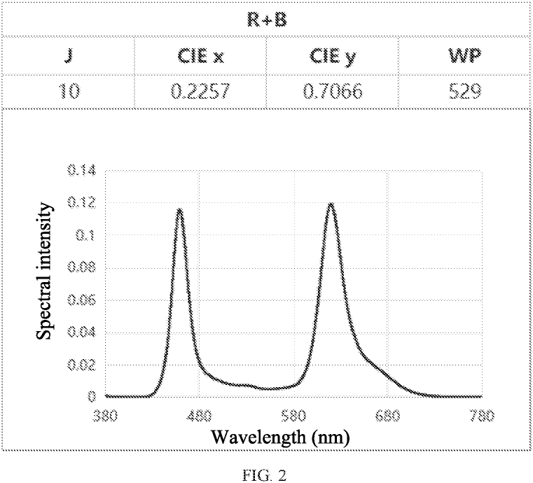

As shown in FIG. 2, the light-emitting region corresponding to the first ITO anode layer forms the R peak plus B peak spectrum. The R filter and the B filter are coated in the light-emitting region corresponding to the first ITO anode layer by a photolithography process to form the two primary colors, namely R and B.

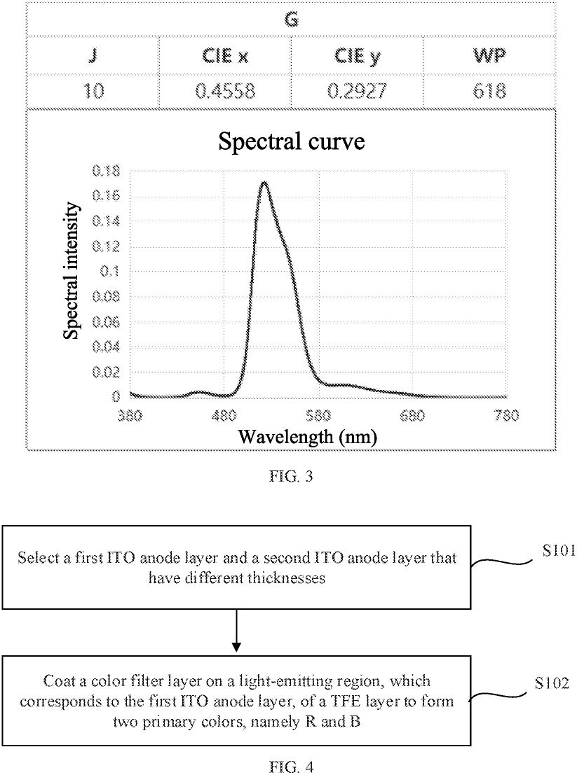

As shown in FIG. 3, the light-emitting region corresponding to the second ITO anode layer forms the G peak spectrum, which forms the primary color G without the CF process.

In a preferred implementation of the present disclosure, in the equation for calculating the thickness of the organic layer of the OLED display device:
n is 1.75;
λ_{R} is 618 nm, λ_{G} is 530 nm, and λ_{B} is 460 nm;
d_{RB} is 530 nm; and
d_{G} is 454 nm or 605 nm.

The selection of the thicknesses of the first ITO anode layer and the second ITO anode layer is described as follows.

The equation for calculating the thickness of the organic layer of the OLED display device is:

$$\sum n {d}_{\text{i}} + \frac{ϕ}{4 π} {λ}_{\text{i}} = m \times \frac{{λ}_{\text{i}}}{2} ;$$

where n denotes a refractive index of an organic functional layer in the OLED display device; dᵢ denotes the thickness of the organic functional layer; λᵢ denotes a resonance-enhanced wavelength of a microcavity in the OLED display device; i denotes a type of a light-emitting unit; ϕ denotes a phase shift of light reflected on surfaces of a metal anode and a metal cathode in the OLED display device; and m denotes an order of an emission mode, also known as a microcavity order, which is a positive integer.

In this implementation, to simplify calculations and perform theoretical simulations, in this structure, let a refractive index of the organic layer be n=1.75, a wavelength of R be λ_{R}=618 nm, a wavelength of G be λ_{G}=530 nm, and a wavelength of B be λ_{B} =460 nm. The phase shift of light at the metal cathode layer and the metal anode layer is ignored, and let m=1, 2, 3,..., N. The thicknesses of the organic layers, which correspond to the R, G, and B light-emitting layers, of the OLED display device are shown in Table 1.

| | m=1 | m=2 | m=3 | m=4 | m=5 | m=6 | m=7 | m=8 | m=9 | ⋯⋯ | m=N |
|---|---|---|---|---|---|---|---|---|---|---|---|
| R | 176.6 | 353.2 | 529.8 | 706.4 | 853 | 1059.6 | 1236.2 | 1412.8 | 1589.4 | ⋯⋯ | 176.6 N |
| G | 151.4 | 302.8 | 454.2 | 605.6 | 757 | 908.4 | 1059.8 | 1211.2 | 1362.6 | ⋯⋯ | 151.4 N |
| B | 131.4 | 262.8 | 394.2 | 525.6 | 657 | 788.4 | 919.8 | 1051.2 | 1182.6 | ⋯⋯ | 131.4 N |

According to the above table, the thicknesses of the first ITO anode layer and the second ITO anode layer are selected. In the 3N-order R/4N-order B/3N-order G, the total thickness corresponding to the R light-emitting unit and the B light-emitting unit is 530 nm, and the total thickness corresponding to the G light-emitting unit is 454 nm. If the thickness of the first ITO anode layer is set to 100 nm, the thickness of the second ITO anode layer is 20 nm. In the 3N-order R/4N-order B/4N-order G, the total thickness corresponding to the R light-emitting unit and the B light-emitting unit is 530 nm, and the total thickness corresponding to the G light-emitting unit is 605 nm. If the thickness of the first ITO anode layer is set to 20 nm, the thickness of the second ITO anode layer is 95 nm.

It should be noted that the total thickness, which corresponds to the R light-emitting unit and the B light-emitting unit, is 530 nm and covers the 3N-order R and the 4N-order B. The total thickness corresponding to the G light-emitting unit is preferably 454 nm (3N-order) or 605 nm (4N-order), which can be any order theoretically. Therefore, the 3N-order R and 4N-order B are selected to be in the same microcavity (N=1, 2, 3...), and any order (preferably 3N to 4N-order) of the G light-emitting unit can be selected.

In conclusion, the present disclosure overcomes the problem that the top-emission WOLED with a single optical thickness in the prior art is prone to color shift because the R, G, and B lights correspond to optical microcavities with different thicknesses.

The preferred implementations of the present disclosure are described above in detail with reference to the drawings, but the present disclosure is not limited to the specific details in the above implementations. Simple variations can be made to the technical solutions of the present disclosure without departing from the technical ideas of the present disclosure, and these simple variations fall within the protection scope of the present disclosure.

In addition, it should be noted that various specific technical features described in the above specific implementations can be combined in any suitable manner if there is no contradiction. To avoid unnecessary repetition, various possible combination modes of the present disclosure are not described separately.

In addition, different implementations of the present disclosure can also be combined arbitrarily. The combinations should also be regarded as falling within the scope of the present disclosure, provided that they do not violate the ideas of the present disclosure.

What is claimed is:

1. A full-color silicon-based organic light-emitting diode (OLED) display device, comprising a base plate, a metal anode, an organic functional layer, a metal cathode, a thin film encapsulation (TFE) layer, and a color filter layer, wherein the base plate, the metal anode_{,} the organic functional layer, the metal cathode, the TFE layer, and the color filter layer are sequentially stacked from bottom to top;
wherein the metal anode comprises a first indium tin oxide (ITO) anode layer and a second ITO anode layer, and the first ITO anode layer and the second ITO anode layer have different thicknesses;
wherein the color filter layer comprises a red (R) filter and a blue (B) filter, and the R filter and the B filter are respectively coated on a light-emitting region of the TFE layer; and
wherein the light-emitting region corresponds to the first ITO anode layer.

2. The full-color silicon-based OLED display device according to claim 1, wherein the organic functional layer comprises a hole injection layer, a hole transport layer, a light-emitting layer, an electron transport layer, and an electron injection layer, and the hole injection layer, the hole transport layer, the light-emitting layer, the electron transport layer, and the electron injection layer are sequentially arranged from bottom to top; and
wherein the light-emitting layer comprises an R light-emitting unit, a B light-emitting unit, and a green (G) light-emitting unit.

3. The full-color silicon-based OLED display device according to claim 1, wherein the base plate is a single-crystal silicon chip.

4. A full-color silicon-based OLED display method, comprising:
selecting a first ITO anode layer and a second ITO anode layer, wherein the first ITO anode layer and the second ITO anode layerhave different thicknesses; and
coating a color filter layer on a light-emitting region of a TFE layer to form two primary colors, namely R and B, wherein the light-emitting region corresponds to the first ITO anode layer.

5. The full-color silicon-based OLED display method according to claim 4, further comprising:
respectively calculating a thickness d_{RB} of a first organic layer of an OLED display device and a thickness d_{G} of a second organic layerof the OLED display device by an equation, wherein the first organic layer corresponds to an R light-emitting unit and a B light-emitting unit, and the second organic layer corresponds to a G light-emitting unit; and
deriving a relationship between a thickness of the first ITO anode layer and a thickness of the second ITO anode layer from the thickness of the first organic layer and the thickness of the second of the OLED display device, wherein
the equation for calculating the thickness of the first organic layer of the OLED display device or the thickness of the second organic layer of the OLED display device is:
$$\sum n {d}_{\text{i}} + \frac{ϕ}{4 π} {λ}_{\text{i}} = m \times \frac{{λ}_{\text{i}}}{2} ;$$
wherein n denotes a refractive index of an organic functional layer in the OLED display device; dᵢ denotes a thickness of the organic functional layer; λᵢ denotes a resonance-enhanced wavelength of a microcavity in the OLED display device; i denotes a type of a light-emitting unit; ϕ denotes a phase shift of light reflected on surfaces of a metal anode and a metal cathode in the OLED display device; and m is a positive integer and denotes an order of an emission mode, also known as a microcavity order.

6. The full-color silicon-based OLED display method according to claim 5, wherein in the equation for calculating the thickness of the first organic layer of the OLED display device or the thickness of the second organic laver of the OLED display device:
n is 1.75;
λ_{R} is 618 nm, λ_{G} is 530 nm, and λ_{B} is 460 nm;
d_{RB} is 530 nm; and
d_{G} is 454 nm or 605 nm.

7. The full-color silicon-based OLED display method according to claim 4, wherein the color filter layer comprises an R filter and a B filter.

8. The full-color silicon-based OLED display method according to claim 4, wherein the color filter layer is coated on the light-emitting region of the TFE layer by a photolithography process, and wherein the light-emitting region corresponds to the first ITO anode layer.

9. The full-color silicon-based OLED display method according to claim 4, wherein after coating the color filter layer on the light-emitting region corresponding to the first ITO anode layer of the TFE layer, the full-color silicon-based OLED display method further comprises:
designing a display driver integrated circuit (IC) to enable an OLED display device to realize a full-color display.
